(19) United States
(12) Patent Application Publication
(10) Pub. No.: US 2025/0076379 A1
(43) Pub. Date: Mar. 6, 2025

(54) EYE-DIAGRAM INDEX ANALYTIC METHOD, COMPUTER READABLE RECORDING MEDIUM, AND ELECTRONIC APPARATUS

(71) Applicant: Novatek Microelectronics Corp., Hsinchu (TW)

(72) Inventors: Kai Li, New Taipei City (TW); Chiu-Chih Chou, Taoyuan City (TW); Ruey-Beei Wu, Taipei City (TW); Hsin-Chan Hsieh, New Taipei City (TW); Ren-Yu Wang, Hsinchu City (TW); Hao-Hsiang Chuang, New Taipei City (TW); Wei-Da Guo, Hsinchu City (TW)

(73) Assignee: Novatek Microelectronics Corp., Hsinchu (TW)

(21) Appl. No.: 18/614,731

(22) Filed: Mar. 24, 2024

Related U.S. Application Data
(60) Provisional application No. 63/536,436, filed on Sep. 4, 2023.

(30) Foreign Application Priority Data
Dec. 19, 2023 (TW) 112149437

(51) Int. Cl. G01R 31/3185; G01R 31/317

(52) U.S. Cl. CPC G01R 31/31855; G01R 31/31711

(57) ABSTRACT

An eye-diagram index analytic method includes: calculating a transfer function of multiple coupled lines; converting the transfer function into a pulse response; calculating an eye-diagram index according to the pulse response; and correcting the eye-diagram index according to peak distortion analysis.

### CROSS-REFERENCE TO RELATED APPLICATION

This application claims the priority benefit of U.S. provisional application Ser. No. 63/536,436, filed on Sep. 4, 2023, and Taiwan application serial no. 112149437, filed on Dec. 19, 2023. The entirety of each of the above-mentioned patent applications is hereby incorporated by reference herein and made a part of this specification.

### BACKGROUND

### Technical Field

The disclosure relates to a signal analytic method, a computer readable recording medium, and an electronic apparatus, and in particular to an eye-diagram index analytic method, a computer readable recording medium, and an electronic apparatus.

### Description of Related Art

Today's technology is booming, and various electronic products have gradually become an indispensable part of lives. Electronic products close to personal life, such as wearable devices, computers, smartphones, and tablets, are continuously innovating. Among these products, double data rate (DDR) synchronous dynamic random access memory (SDRAM) is an essential component. With the evolution of DDR, the speed thereof gradually increases. As the usage bandwidth of DDR becomes higher and higher, how to effectively transmit data becomes even more crucial.

DDR modules serve as the primary bridge for storage and the processor, achieving data transmission through multiple transmission lines. However, the lines can couple with each other, thereby generating crosstalk. Particularly in cases with multiple channels, far-end crosstalk (FEXT) caused by crosstalk aggressors at the receiver end becomes one of the bottlenecks in increasing data rates. Simultaneously, when the transmitter end and the receiver end are not matched properly, FEXT and near-end crosstalk (NEXT) also adversely affect signal integrity.

In this situation, to ensure high-quality transmission of the DDR modules, it is necessary to analyze and measure signal integrity, and it is necessary to be able to quickly find the worst-case sequences on the transmission lines. In the prior art, simulating eye diagrams using pseudorandom binary sequences (PRBS) is very time-consuming. Generating the worst-case eye diagram for inter symbol interference (ISI) caused by FEXT and NEXT requires a specific sequence, and obtaining the worst-case sequences for different lines simultaneously using PRBS is highly challenging. Therefore, there is a need to develop a fast method to find the worst-case sequences on the transmission lines to ensure high-quality transmission of the DDR modules.

### SUMMARY

Embodiments of the disclosure provide an eye-diagram index analytic method, a computer readable recording medium, and an electronic apparatus. The eye-diagram index analytic method can effectively find worst-case sequence patterns on multiple transmission lines in multiple channels.

The eye-diagram index analytic method according to the embodiment of the disclosure includes the following steps. A transfer function of multiple coupled lines is calculated. The transfer function is converted into a pulse response. An eye-diagram index is calculated based on the pulse response. The eye-diagram index is corrected based on peak distortion analysis.

The computer readable recording medium according to the embodiment of the disclosure includes a computer program enabling a computer to execute the eye-diagram index analytic method after executing the computer program.

The electronic apparatus according to the embodiment of the disclosure includes a processor and a storage element. The storage element stores a computer program enabling a processor to execute the eye-diagram index analytic method after executing the computer program.

In order for the features and advantages of the disclosure to be more comprehensible, the following specific embodiments are described in detail in conjunction with the drawings.

### BRIEF DESCRIPTION OF THE DRAWINGS

FIG. 1 is an eye diagram of good signal quality.

FIG. 2 shows an eye diagram of poor signal quality.

FIG. 3 is a schematic diagram of a signal path of an insertion loss response according to an embodiment of the disclosure.

FIG. 4 is a schematic diagram of a signal path of a far-end crosstalk response according to an embodiment of the disclosure.

FIG. 5 is a schematic diagram of an insertion loss response according to an embodiment of the disclosure.

FIG. 6 is a schematic diagram of a far-end crosstalk response according to an embodiment of the disclosure.

FIG. 7 is a schematic diagram of a main cursor according to an embodiment of the disclosure.

FIG. 8 is a schematic diagram of a worst eye height at a main cursor sampling time point according to an embodiment of the disclosure.

FIG. 9 is a schematic diagram of a single transmission line where both transmitter and receiver ends are mismatched according to an embodiment of the disclosure.

FIG. 10 is a schematic diagram of multiple coupled lines where both ends are mismatched according to an embodiment of the disclosure.

FIG. 11 is a schematic diagram of a capacitor connected in parallel at both a transmitter end and a receiver end according to an embodiment of the disclosure.

FIG. 12 is a schematic diagram of a DDR4 circuit according to an embodiment of the disclosure.

FIG. 13 is a schematic diagram of a CMOS output buffer according to an embodiment of the disclosure.

FIG. 14 is a schematic diagram of a linear equivalent circuit of a transmitter according to an embodiment of the disclosure.

FIG. 15 is a schematic diagram of a linear equivalent circuit of a receiver according to an embodiment of the disclosure.

FIG. 16 is a schematic diagram of linear equivalent circuits at SOC and DRAM ends during a ‘write’ mode according to an embodiment of the disclosure.

FIG. 17 is a schematic diagram of a linear equivalent circuit at SOC and DRAM ends during a ‘read’ mode according to an embodiment of the disclosure.

FIG. 18 is a schematic diagram of a DDR4 circuit according to another embodiment of the disclosure.

FIG. 19 is a schematic diagram of S-parameters including power supply line ports according to an embodiment of the disclosure.

FIG. 20 is a schematic diagram of a clock signal sequence according to an embodiment of the disclosure.

FIG. 21 is a schematic diagram of a worst-case sequence eye diagram according to an embodiment of the disclosure.

FIG. 22 is a block schematic diagram of an electronic apparatus according to an embodiment of the disclosure.

FIG. 23 is a flowchart of steps of an eye-diagram index analytic method according to an embodiment of the disclosure.

FIG. 24 is a block schematic diagram of an electronic apparatus according to another embodiment of the disclosure.

FIG. 25 is a schematic diagram of a worst eye width according to an embodiment of the disclosure.

FIG. 26 is a schematic diagram of a worst center eye height according to an embodiment of the disclosure.

FIG. 27 is a schematic diagram of a box eye width according to an embodiment of the disclosure.

### DESCRIPTION OF THE EMBODIMENTS

An embodiment of the disclosure provides an eye-diagram index analytic method, which can effectively find worst-case sequence patterns on multiple transmission lines in multiple channels. Existing methods need to consider a large number of sequence combinations, which are very computationally intensive and time-consuming. Therefore, an embodiment of the disclosure provides an eye-diagram index based on a peak distortion analysis (PDA) method of a pulse response. Through extending the pulse response to multiple transmission lines, the worst-case sequence patterns on the transmission lines can be quickly found, and the eye-diagram index is calculated to quickly analyze the quality of signal integrity. Such a method can find the worst-case sequence patterns in a short time to calculate the eye-diagram index, thereby saving a lot of time and calculations in simulating an eye diagram.

Taking a double data rate (DDR) module as an example, the DDR module is one of the most common memory modules in today's computer motherboards and other equipment. With the development of integrated circuit manufacturing technology, the data transmission rate of DDR is getting higher and higher, reaching the gigabit per second (Gbps) level. However, higher and higher data transmission rates and shorter and shorter signal rising and falling times have brought challenges to system signal integrity. In the design of the DDR module, signals are simultaneously transmitted by multiple transmission lines, and often due to cost considerations, the transmission lines are very close together. Therefore, special attention needs to be paid to issues such as transmission delay, reflection, and crosstalk. The issues can cause damage to signal integrity, thereby causing incorrect transmission of data or a reduction in transmission rate. The eye diagram can be used to evaluate the signal integrity of the DDR module and can help a designer understand the signal transmission status and degree of damage, so that appropriate optimization measures can be taken in the design. For example, if an opening of the eye diagram becomes smaller or distorted, the designer may consider ways such as increasing the power of a driver or reducing the length of a transmission line to improve signal integrity.

An embodiment of the disclosure provides an eye-diagram index analytic method. By inputting S-parameters, a pulse response with boundaries containing mismatched linear elements can be calculated through a derived transfer function, and an eye-diagram index is calculated based on a PDA.

The eye diagram is composed of a series of overlapping pulse responses, and each waveform represents a signal sample at a different time point. When a continuous digital signal is interfered or distorted during transmission, the shape of the signal waveform changes. Through combining the waveforms, the deformation of a signal may be observed.

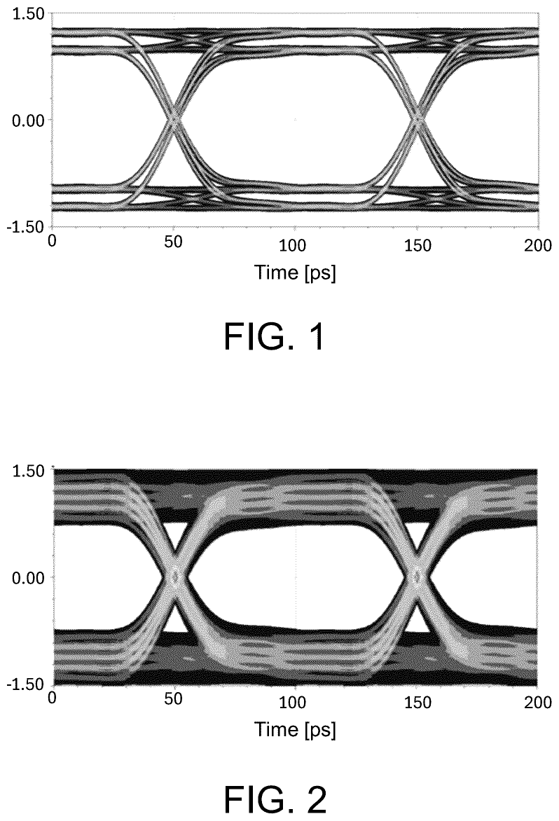

The main objective of the eye diagram is to evaluate the signal quality of a system in high-speed data transmission and to detect issues in data transmission. For example, the eye diagram may be used to detect issues such as signal distortion, timing offset, and spurious interference. Through analyzing the eye diagram, the characteristics of a signal may be further understood, thereby optimizing the design of a transmission system and improving signal quality. As shown in FIG. 1 and FIG. 2, FIG. 1 shows wider eyes, and the eye height and the eye width are both greater than those in FIG. 2, which means that the system of FIG. 1 has better signal integrity.

Generally, the eye diagram is simulated using a pseudorandom binary sequence (PRBS). However, the amount of data generated by the PRBS is very large, and the analysis and evaluation processes often need a lot of time and resources. Therefore, in order to improve efficiency, the PDA may be adopted to analyze the worst-case eye diagram. The PRBS stands for the pseudorandom binary sequence, which is a digital signal. The PRBS is a binary sequence generated by a set of pseudorandom number generators and has random statistical properties. For example, the numbers of “0” and “1” of the PRBS signal are approximately equal. The PRBS is often used as an input signal for simulating the eye diagram to evaluate the performance of a digital system. However, in actual situations, there are usually many channels. Since the eye diagram generated by the PRBS is only representative when the length is long enough, it will be very time-consuming to use the PRBS to simulate the eye diagram for multiple channels. Also, the ISI of crosstalk on the main signal needs a specific sequence to generate the worst-case eye diagram. In the case of multiple channels, finding the worst-case sequence through peak distortion analysis (PDA) based on the pulse response is the current trend.

In a linear time-invariant (LTI) system, the pulse responses of the system at different times are superimposed on each other. Therefore, the inter symbol interference may be calculated from a single pulse response, thereby finding the worse-case sequence of the eye diagram. The LTI system means that there is a linear relationship between the input and the output of the system, but parameters of the system do not change over time. In other words, the response of the system to input is fixed and does not change over time.

In the LTI system, a series of signals may be regarded as the superposition of many signals. If a symbol is completely transmitted and the waveform has not completely disappeared, it will cause interference to the transmission of the next symbol. Such an interference is referred to as the inter symbol interference. The influence of the inter symbol interference may be calculated through analyzing the pulse response.

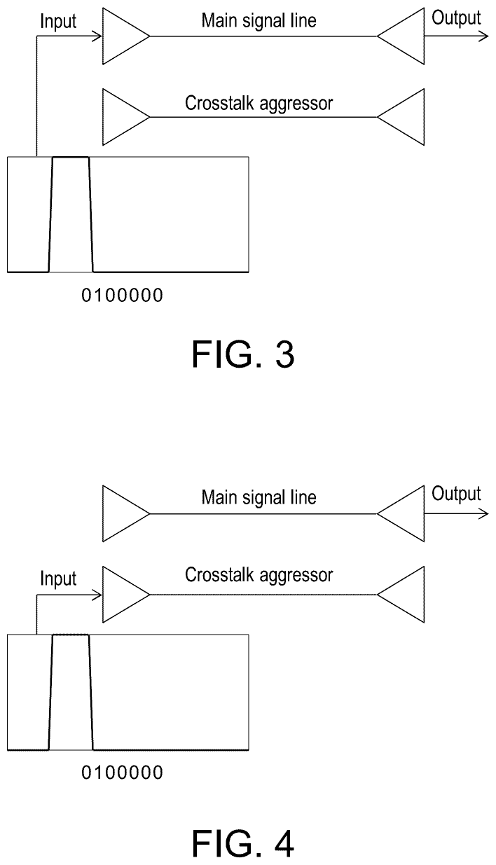

In the LTI digital system, if the input signals are a series of “1” and “0”, since it is an LTI system, the series of signals may be regarded as many single trapezoidal waves at different times as the input signals to be then superimposed together. In a circuit with multiple transmission lines, the pulse responses may be divided into two types, and the first type is an insertion loss response. As shown in FIG. 3, the signal of the single trapezoidal wave is the signal sequence of “0100000”, which is sent by the transmitter end of the main signal line, and what the receiver end of the main signal line receives is the insertion loss response. The second type is a far-end crosstalk (FEXT) response. As shown in FIG. 4, the signal of the single trapezoidal wave is the signal sequence of “0100000”, which is sent by the transmitter end of a crosstalk active end, and what the receiver end of the main signal line receives is the far-end crosstalk response.

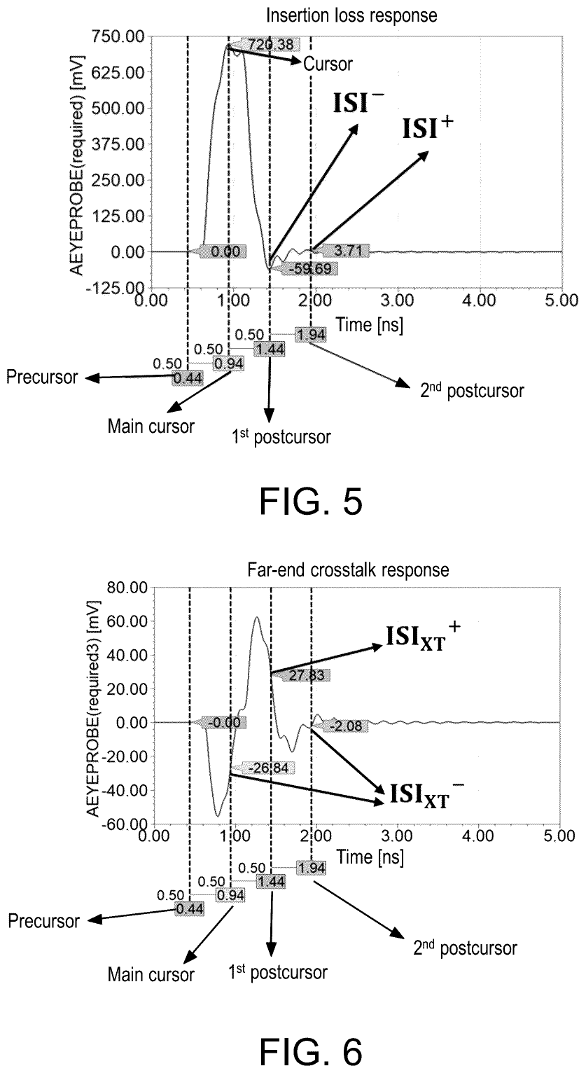

As shown in the insertion loss response of FIG. 5, a cursor is defined as a main cursor. The time one unit time interval (UI) before the main cursor is defined as a precursor, and the time n UIs after the main cursor is defined as an n^{th} postcursor, wherein UI represents the unit interval between two consecutive bits. Due to system response, neither the precursor nor the n^{th} postcursor returns to the 0 level, and the interferences are the inter symbol interferences. Sampling points greater than 0 are defined as ISI+, as shown by the 2^{nd} postcursor of FIG. 5, and sampling points less than 0 are defined as ISI−, as shown by the 1^{st} postcursor of FIG. 5.

In the circuit with multiple transmission lines, crosstalk also causes the inter symbol interference, as shown by the far-end crosstalk response of FIG. 6. At the same sampling points as the previous insertion loss response, there is an ISI_{XT}+ sampling point, such as the 1^{st} postcursor, and ISI_{XT}− sampling points, such as the main cursor and the 2^{nd} postcursor. Then, the worst case 1-level and the worst case 0-level may be listed:

$$Worst case 0 = \sum \vert {ISI}^{+} \vert + \sum \vert {ISI}_{XT}^{+} \vert \qquad ( 1 )$$

$$Worst case 1 = cursor - \sum \vert {ISI}^{-} \vert - \sum \vert {ISI}_{XT}^{-} \vert \qquad ( 2 )$$

It can be seen from (1) that the worst-case bit 1 is only affected by the cursor and negative ISI, so negative ISI corresponds to bit 1, and positive ISI corresponds to bit 0; and vice versa for the worst-case bit 0.

In the insertion loss response of FIG. 5, since the value of the precursor is 0, the precursor is not considered for the time being. The worst-case bit 1 for the transmitter end of the main signal line is “0 1 1”. First, the main cursor corresponds to the cursor, so the last digit of the worst-case bit 1 is “1”, the 1^{st} postcursor corresponds to negative ISI, so the second last digit of the worst-case bit 1 is “1”, and the 2^{nd} postcursor corresponds to positive ISI, so the third last digit of the worst-case bit 1 is “0”; and the worst-case bit 0 is the inverse of the worst-case bit 1, “1 0 0”.

In the far-end crosstalk response of FIG. 6, since the value of the precursor is also 0, the precursor is not considered for the time being. The worst-case bit 1 for the transmitter end of the crosstalk active side is “1 0 1”. The main cursor, the 1^{st} postcursor, and the 2^{nd} postcursor respectively correspond to negative, positive, and negative ISI. Therefore, the last digit, the second last digit, and the third last digit of the worst-case bit 1 correspond to “1”, “0”, and “1”; and the worst-case bit 0 is “0 1 0”.

After obtaining the worst-case bits 1 and the worst-case bits 0 of the main signal line and all coupled lines, the worst-case bits may be connected in series as the worst-case sequence of the eye diagram of each line to be used as the input signal of the transmitter end of each line, so that the worst-case eye diagram may be obtained.

The eye-diagram index is first explained below, and the transfer function of a single transmission line is then derived, thereby extending to the transfer function of multiple coupled lines to quickly establish the pulse response of multiple transmission lines and calculate the eye-diagram index.

First, the eye-diagram index is explained. In the embodiment of the disclosure, the eye-diagram index at least includes the worst eye width and the worst center eye height, as described below.

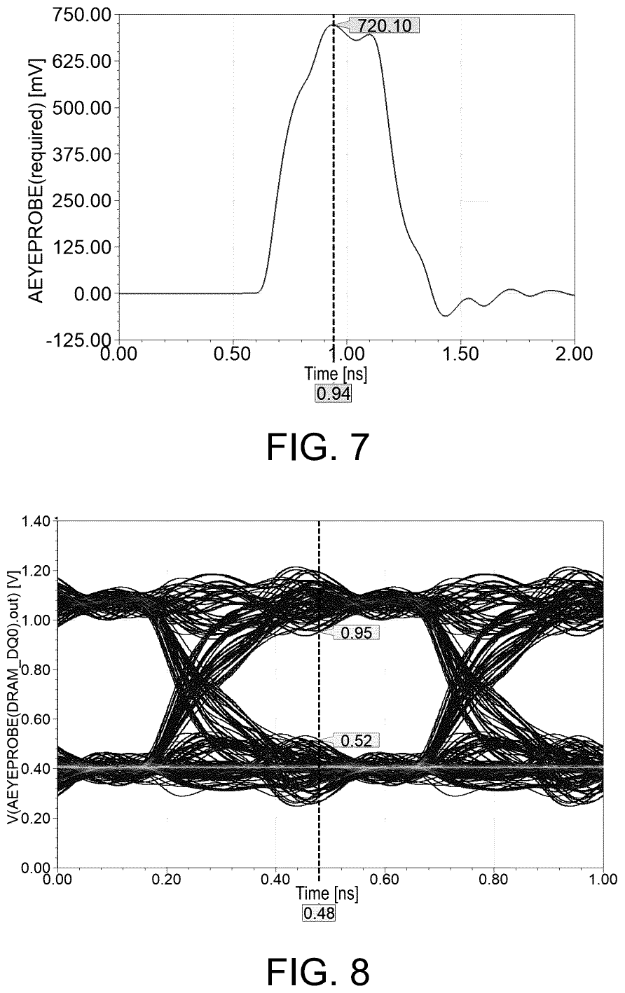

From (1) and (2), the worst case 1-level and 0-level may be calculated. Therefore, the worst case 1-level may be deducted from 0-level to calculate the worst eye height at the sampling time point of the main cursor, as shown by (3). The dotted line of FIG. 7 represents the main cursor, and the dotted line and the marking of FIG. 8 represent the worst eye height at the sampling point of the main cursor.

$$\begin{matrix}Worst eye height \\ = cursor - \sum \vert {ISI}^{-} \vert - \sum \vert {ISI}_{XT}^{-} \vert -= cursor - \sum \vert {ISI}^{+} \vert - \sum \vert {ISI}_{XT}^{+} \vert\end{matrix} \qquad ( 3 )$$

It can be seen that when calculating the worst eye height, whether it is positive or negative ISI, the absolute value is added and then subtracted. Therefore, the values of different sampling points may also be used to rewrite (3) to obtain (4):

$$\begin{matrix}Worst eye height \\ = cursor - \sum \vert {ISI}^{-} \vert - \sum \vert {ISI}_{XT}^{-} \vert -= cursor - \sum \vert {ISI}^{+} \vert - \sum \vert {ISI}_{XT}^{+} \vert \\ - \sum \sum \vert xtk {cursor}^{j} \vert\end{matrix} \qquad ( 4 )$$

where main cursor represents the cursor value of the main signal line, postcursor represents the ISI value of different postcursors of the main signal line, precursor represents the ISI value of different precursors of the main signal line, and xtk cursor represents the ISI value of each sampling point on all coupled lines.

The values of the cursor, the postcursor, etc. in (4) may be calculated using (5) to obtain (6) and (7):

$${V}_{SBR} ( t ) = {\int }_{- ∞}^{∞} H ( f ) {V}_{i} ( f ) {e}^{j 2 π ft} df \approx {\int }_{- {f}_{0}}^{{f}_{0}} H ( f ) {V}_{i} ( f ) {e}^{j 2 π ft} df \qquad ( 5 )$$

where V_{SBR}(t) is the pulse response. However, in practical applications, the bandwidth of the transfer function is limited, such as the S-parameter with limited bandwidth, so the bandwidth may only be estimated using the integral of limited frequency. Vᵢ(f) is the input signal, which is the single trapezoidal wave. H(f) is the transfer function of the system.

$${main}_{k} = {\int }_{- {f}_{0}}^{{f}_{0}} {H}_{xtk} ( f ) {V}_{i} ( f ) {e}^{j 2 π f [ τ + l \cdot UI ]} df \qquad ( 6 )$$

$${xtk}_{l} = {\int }_{- {f}_{0}}^{{f}_{0}} {H}_{xtk} ( f ) {V}_{i} ( f ) {e}^{j 2 π f [ τ + l \cdot UI ]} df \qquad ( 7 )$$

where main represents values of the cursor, the postcursor, etc. of the main signal line, xtk represents the xtk cursor, and k and 1 represent different sampling points. For example, k=0 represents the main cursor, k=1 represents the 1^{st} postcursor, Hₘₐᵢₙ(f) and Hₓₜₖ(f) respectively represent the transfer functions of the insertion loss response and the far-end crosstalk response, Vᵢ(f) is the input signal, that is, the single trapezoidal wave, and τ represents the time delay from the transmitter end to the receiver end on the main signal line plus the time difference of different sampling points of the main cursor.

In (6) and (7), it can be seen that the integration range is from −f0 to f0. However, the transfer functions Hₘₐᵢₙ(f) and Hₓₜₖ(f) in the integration include the S-parameters, but in the actual situations, the S-parameters do not include negative frequencies, but by the property that a pulse function h(t) and a single trapezoidal wave Vi(t) of a signal only have a value when t>0, (8) and (9) may be obtained, and (10) and (11) may then be listed:

$$H ( - f ) = {H}^{*} ( f ) \qquad ( 8 )$$

$${V}_{i} ( - f ) = {V}_{i}^{*} ( f ) \qquad ( 9 )$$

$${main}_{k} = 2 {\int }_{0}^{{f}_{0}} Re \{ {V}_{i} ( f ) {H}_{main} ( f ) {e}^{j 2 π f [ τ + k \cdot UI ]} df \qquad ( 10 )$$

$${xtk}_{l} = 2 {\int }_{0}^{{f}_{0}} Re \{ {V}_{i} ( f ) {H}_{xtk} ( f ) {e}^{j 2 π f [ τ + k \cdot UI ]} \} df \qquad ( 11 )$$

where (10) and (11) may be calculated using fast Fourier transform. In order to reduce an interval Δt in the time domain to improve the resolution in the time domain, zero padding may be used to lengthen the total number of points to the required number of points N, and (12) may be listed:

$$N = round ( \frac{1}{Δ t Δ f} ) \qquad ( 12 )$$

where Δt is the specified interval point in the time domain, Δf is the interval point in the frequency domain, and N is the total number of points after zero padding. Finally, (10) and (11) may be rewritten as (13) and (14) in fast Fourier transform forms:

$$main = \frac{2}{Δ t} * R e \{ if f t ( {V}_{i} ( f ) {H}_{mαin} ( f ) ) \} \qquad ( 13 )$$

$$xtk = \frac{2}{Δ t} * R e \{ if f t ( {V}_{i} ( f ) {H}_{xtk} ( f ) ) \} \qquad ( 14 )$$

where main represents the insertion loss response of the main signal line, and xtk represents the far-end crosstalk response caused by the coupled line. Then, (4) may be rewritten as (15):

$$Worst eye height = {main}_{0} - {\sum }_{k = - L \& k \neq 0}^{N} \vert {main}_{k} \vert - {\sum }_{j} {\sum }_{l = - P}^{M - 1} \vert {xtk}_{l}^{j} \vert \qquad ( 15 )$$

where N represents the number of postcursors considered on the main signal line, L represents the number of precursors considered on the main signal line, M represents the number of xtk cursors considered on the coupled line, P represents the number of xtk precursors considered on the coupled line, and j represents different coupled lines.

Then, the worst eye height at different sampling time points may be obtained from (15), wherein positions where the worst eye height equals zero on two sides of the eye are the left and right endpoints, and the sampling time points are τ_{right} and τ_{left}. The two sampling time points are subtracted to obtain the worst eye width (16). Then, through calculating the midpoint of the left and right endpoints (17), the worst center eye height may also be obtained (18), and (16), (17), and (18) may be respectively listed:

$${Index}_{width} = {τ}_{right} - {τ}_{left} \qquad ( 16 )$$

$${τ}_{middle} = \frac{{τ}_{right} - {τ}_{left}}{2} + {τ}_{left} \qquad ( 17 )$$

$${Index}_{height} = Worst eye height {\vert}_{τ = {τ}_{middle}} \qquad ( 18 )$$

Therefore, in the embodiment of the disclosure, the eye-diagram index at least includes the worst eye width and the worst center eye height.

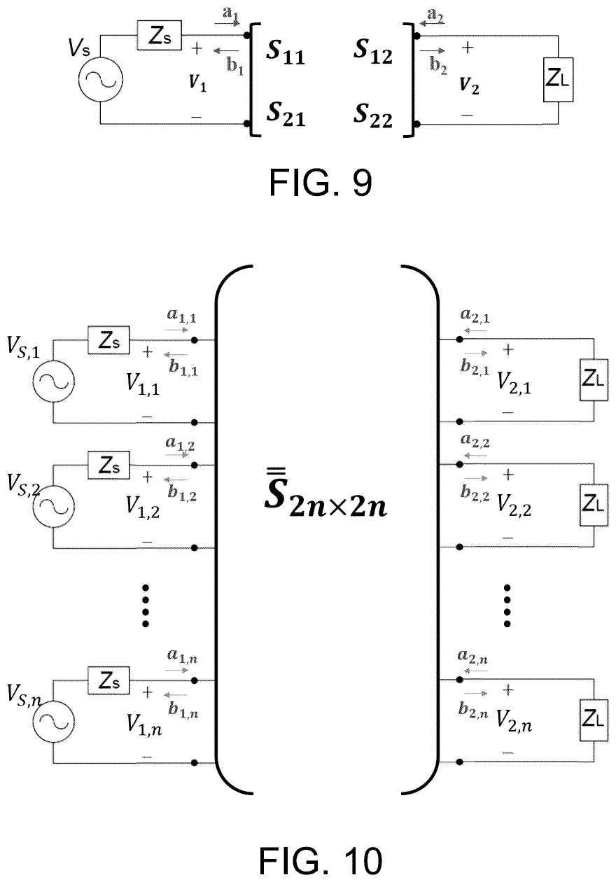

Next, the transfer function of a single transmission line is explained. In order to obtain the transfer function where both the transmitter end and the receiver end are mismatched, a single transmission line as shown in FIG. 9 may be first considered. An S-parameter matrix may be defined as:

$$( \begin{matrix}i \\ {b}_{2}\end{matrix} ) = {S}^{=} ( \begin{matrix}{a}_{1} \\ {a}_{2}\end{matrix} ) = ( \begin{matrix}{S}_{11} & {S}_{12} \\ {S}_{21} & {S}_{22}\end{matrix} ) ( \begin{matrix}{a}_{1} \\ {a}_{2}\end{matrix} )$$

where a₁ and a₂ are respectively transmission waves at the transmitter end and the receiver end; and b₁ and b₂ are respectively reflection waves at the transmitter end and the receiver end.

In terms of transmission lines, the distortion of the signal transmitted from the transmitter end to the receiver end must be within an acceptable range. The S-parameters may be used to measure the influence on signals in the frequency domain when the transmission lines are interconnected, that is, the frequency domain characteristics of the signal may be observed through the S-parameters. An electronic element between the transmission lines may be equivalently described as an S-parameter matrix and be used to analogize the behavior of the electronic element at different frequencies.

A transfer function V₂/V_{S} of a single transmission line where both the transmitter end and the receiver end are mismatched may be derived as:

$$\frac{{V}_{2}}{{V}_{S}} = \frac{( 1 - {Γ}_{S} ) ( 1 + {Γ}_{L} )}{2} ( \begin{matrix}0 & 1\end{matrix} ) {{A}^{=}}^{- 1} ( \begin{matrix}{S}_{11} \\ {S}_{21}\end{matrix} ) \qquad ( 19 )$$

where Γ_{S} and Γ_{L} are reflection coefficients of the transmitter end and the receiver end, and A̅ is the following matrix:

$$( \begin{matrix}1 - {S}_{11} {Γ}_{S} & - {S}_{12} {Γ}_{L} \\ - {S}_{21} {Γ}_{S} & 1 - {S}_{22} {Γ}_{L}\end{matrix} ) ≡ {A}^{=} \qquad ( 20 )$$

Next, the transfer function of multiple coupled lines (that is, transmission lines) are explained. In order to obtain a transfer function

$$\frac{{V}_{2 , k}}{{V}_{S , m}}$$

of the insertion loss response and the far-end crosstalk response, where k=1˜n and m=1˜n. The single transmission line architecture of FIG. 9 may be extended to multiple coupled lines, as shown in FIG. 10, wherein there are n coupled lines.

First, (21) may be defined from the S-parameter matrix:

$${\begin{matrix}( \begin{matrix}{\vec{b}}_{1} \\ {\vec{b}}_{2}\end{matrix} ) = {S}^{=} ( \begin{matrix}{\vec{a}}_{1} \\ {\vec{a}}_{2}\end{matrix} ) ; & {S}^{=} = ( \begin{matrix}{{S}^{=}}_{11} & {{S}^{=}}_{12} \\ {{S}^{=}}_{21} & {{S}^{=}}_{22}\end{matrix} )\end{matrix}}_{2 n \times 2 n} \qquad ( 21 )$$

where \vec{b}₁=(b_{1,1}, b_{1,2}, . . . , b_{1,n})^{T} is a column vector composed of b_{1,i}, b_{1,i} represents the reflection wave of an i^{th} (where i=1, . . . , n) transmission line at the transmitter end. \vec{b}₂ is analogized and is a column vector composed of the reflection wave at the receiver end; and \vec{a}₁ and \vec{a}₂ are respectively column vectors composed of the transmission waves at the transmitter end and the receiver end.

Since there is no voltage source at the receiver end, the transmission wave is the reflection wave multiplied by the reflection coefficient, so (22) may be listed:

$${\vec{a}}_{2} = {Γ}_{L} {\vec{b}}_{2} \qquad ( 22 )$$

There is a voltage source at the transmitter end, so (23) may be listed:

$${\vec{a}}_{1} = \frac{( 1 - {Γ}_{S} )}{2} {\vec{V}}_{S} + {Γ}_{S} {\vec{b}}_{1} \qquad ( 23 )$$

where \vec{V}_{S}=(V_{S,1}, V_{S,2}, . . . V_{S,n})^{T} is the column vector composed of a voltage source V_{S,i} at the transmitter end. Then, (22) and (23) may be substituted into (21) and sorted into:

$$( \begin{matrix}{\vec{a}}_{1} \\ {\vec{a}}_{2}\end{matrix} ) = ( \begin{matrix}{Γ}_{S} {{1}^{=}}_{n} & {{0}^{=}}_{n} \\ {{0}^{=}}_{n} & {Γ}_{L} {{1}^{=}}_{n}\end{matrix} ) ( \begin{matrix}{\vec{b}}_{1} \\ {\vec{b}}_{2}\end{matrix} ) \frac{( 1 - {Γ}_{S} )}{2} {( \begin{matrix}{{1}^{=}}_{n} \\ {{0}^{=}}_{n}\end{matrix} )}_{2 n \times n} {\vec{V}}_{S} \qquad ( 24 )$$

where 0̅ₙ represents an n×n zero matrix, 1̅ₙ represents an n×n identity matrix,

$${( \begin{matrix}{{1}^{=}}_{n} \\ {{0}^{=}}_{n}\end{matrix} )}_{2 n \times n}$$

represents that 1̅ₙ is placed above the 2n×n matrix and 0̅ₙ is placed below the 2n×n matrix. Then, a diagonal matrix of the reflection coefficient may be defined as Γ̅:

$${Γ}^{=} ≡ {( \begin{matrix}{Γ}_{S} {{1}^{=}}_{n} & {{0}^{=}}_{n} \\ {{0}^{=}}_{n} & {Γ}_{L} {{1}^{=}}_{n}\end{matrix} )}_{2 n \times 2 n}$$

(24) is substituted back into (21) to obtain:

$$( {{1}^{=}}_{2 n} - {S}^{=} {Γ}^{=} ) ( \begin{matrix}{\vec{b}}_{1} \\ {\vec{b}}_{2}\end{matrix} ) = \frac{( 1 - {Γ}_{S} )}{2} ( \begin{matrix}{{S}_{11}}^{=} \\ {{S}_{21}}^{=}\end{matrix} ) {\vec{V}}_{S}$$

The matrix on the left of the equation is defined as A̅:

$$( {{1}^{=}}_{2 n} - {S}^{=} {Γ}^{=} ) ≡ {A}^{=}$$

Then, inverse matrix of A̅ is found to obtain the relationship between the reflection wave and each voltage source:

$$( \begin{matrix}{\vec{b}}_{1} \\ {\vec{b}}_{2}\end{matrix} ) = \frac{( 1 - {Γ}_{S} )}{2} {{A}^{=}}^{- 1} ( \begin{matrix}{{S}^{=}}_{11} \\ {{S}^{=}}_{21}\end{matrix} ) {\vec{V}}_{S} \qquad ( 25 )$$

Considering the relationship between the reflection wave at the receiver end and a voltage V_{2,k} at the receiver end, (26) may be obtained:

$${\vec{V}}_{2} = ( 1 + {Γ}_{L} ) {\vec{b}}_{2} \qquad ( 26 )$$

where \vec{V}₂=(V_{2,1}, V_{2,2}, . . . V_{2,n})^{T} is the column vector composed of a voltage V_{2,i} at the receiver end. Then, (26) is substituted back into (25) to obtain the following after sorting:

$${\vec{V}}_{2} = \frac{( 1 - {Γ}_{S} ) ( 1 + {Γ}_{L} )}{2} {( \begin{matrix}{{0}^{=}}_{n} & {{1}^{=}}_{n}\end{matrix} )}_{n \times 2 n} {{A}^{=}}^{- 1} ( \begin{matrix}{{S}^{=}}_{11} \\ {{S}^{=}}_{21}\end{matrix} ) {\vec{V}}_{S}$$

where (0̅ₙ 1̅ₙ)_{n×2n} represents that 0̅ₙ is placed on the left side of the n×2n matrix and 1̅ₙ is placed on the right side of the n×2n matrix. Therefore, an n×n transfer function matrix H̅ may be obtained:

$${H}^{=} = \frac{( 1 - {Γ}_{S} ) ( 1 + {Γ}_{L} )}{2} {( \begin{matrix}{{0}^{=}}_{n} & {{1}^{=}}_{n}\end{matrix} )}_{n \times 2 n} {{A}^{=}}^{- 1} ( \begin{matrix}{{S}^{=}}_{11} \\ {{S}^{=}}_{21}\end{matrix} )$$

where the element of H̅ is the transfer function

$$\frac{{V}_{2 , k}}{{V}_{S , m}}$$

of the insertion loss response and the far-end crosstalk response:

$${{H}^{=}}_{km} = \frac{{V}_{2 , k}}{{V}_{S , m}} \qquad ( 27 )$$

k=m is the transfer function of the insertion loss response of a k^{th} signal line. k≠m represents the transfer function of far-end crosstalk caused by an m^{th} signal line to the k^{th} signal line. Therefore, (27) is substituted back into (10) and (11) to obtain the insertion loss response and the far-end crosstalk response.

Next, the transfer function with parallel circuit boundaries is explained. Taking the DDR module as an example, the main storage structure of the DDR module is a DRAM, and the DRAM is composed of a capacitor and a transistor. Therefore, in a linear equivalent circuit, the transmitter end and the receiver end are connected in parallel with the capacitor, as shown in FIG. 11. Z_{L}^{C} is a resistor R_{L} and a capacitor C_{L} at the receiver end connected in parallel, and Z_{S} is a resistor R_{S} at the transmitter end.

A transfer function H̅^{C} with parallel circuit boundaries may be derived as:

$${{H}^{=}}^{{}_{{}_{{}_{C}}}} = \frac{( 1 - {Γ}_{S}^{C} ) ( 1 + {Γ}_{L}^{C} )}{2 ( 1 + j {ωC}_{S} {Z}_{S} )} {( {{0}^{=}}_{n} {{1}^{=}}_{n} )}_{n \times 2 n} {{A}^{=}}^{{}_{{}_{{C}^{- 1}}}} ( \begin{matrix}{{S}^{=}}_{11} \\ {{S}^{=}}_{21}\end{matrix} ) \qquad ( 28 )$$

where the parameters are:

$${Z}_{L}^{C} = \frac{{Z}_{L}}{1 + j {ωC}_{L} {R}_{L}} \\ {Z}_{S} = {R}_{S} \text{?} \\ {V}_{S}^{C} = \frac{1}{1 + j ω {C}_{S} {Z}_{S}} {V}_{S} \\ {Z}_{S}^{C} = \frac{{Z}_{S}}{1 + j {ωC}_{S} {Z}_{S}} \\ {Γ}_{L}^{{}^{{}_{C}}} = \frac{{Z}_{L}^{C} - {Z}_{0}}{{Z}_{L}^{C} + {Z}_{0}} \\ {Γ}_{S}^{{}^{{}_{C}}} = \frac{{Z}_{S}^{C} - {Z}_{0}}{{Z}_{S}^{C} + {Z}_{0}} \\ {Γ}^{=} ≡ {( \begin{matrix}{Γ}_{L}^{{}^{C}} {{1}^{=}}_{n} & {{0}^{=}}_{n} \\ {{0}^{=}}_{n} & {Γ}_{L}^{{}^{C}} {{1}^{=}}_{n}\end{matrix} )}_{2 n \times 2 n} \\ ( {{1}^{=}}_{2 n} - {S}^{=} {{Γ}^{=}}^{{}_{{}_{C}}} ) ≡ {{A}^{=}}^{{}_{{}_{{}_{C}}}}$$

$$\text{?} \text{indicates text missing or illegible when filed}$$

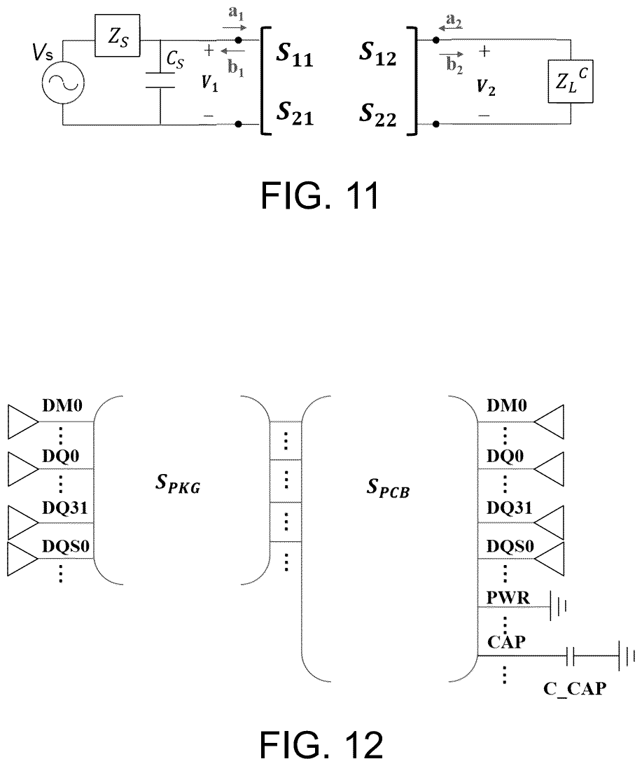

The following takes a DDR4 circuit as an example to illustrate the analysis of the eye-diagram index. FIG. 12 is a DDR4 circuit used for validation according to an embodiment of the disclosure. The transmission path of DDR 4 may be roughly divided into CPU, package (PKG), printed circuit board (PCB), and DRAM, wherein PCB transmits data through multiple equal-length transmission lines, wherein DQ, DM, and DQS are several key signal lines for transmitting data, and DQ stands for “data” or “data lines” and is used to transmit data; DM stands for “data mask” and is used to indicate whether data transmitted on each DQ line is valid, if the signal on the DM line is low, it means that the data transmitted on the corresponding DQ line is invalid; and DQS stands for “data strobe” and is used to indicate the timing of data transmission. A DDR memory uses a DQS signal to synchronize transmission timing during data transmission. In FIG. 12, the S-parameters of the package (PKG) and the printed circuit board (PCB) are considered, which include DQ 0 to DQ 31, DM 0, and DQS0. There is a total of 44 lines. In FIG. 12, the triangle on the left side represents the linear equivalent circuit at a system on a chip (SOC) end, and the triangle on the right side represents the linear equivalent circuit at the DRAM end. Since in the DDR circuit, read and write modes share the same signal line, the circuits at the SOC and DRAM ends switches to the transmitter or receiver mode according to the read and write modes. Therefore, the linear equivalent circuits at two ends are different in the read and write modes.

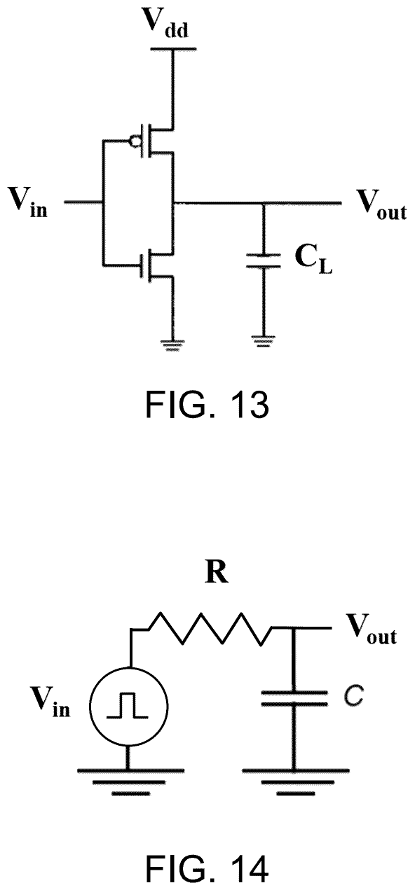

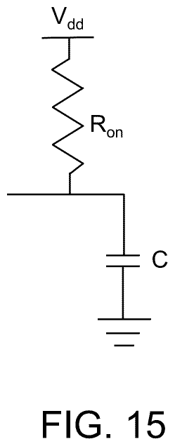

The circuit of the transmitter may be represented by a simple CMOS output buffer, as shown in FIG. 13. Then, the resistance of the inverter may be equivalently calculated through the current-voltage relationship of the inverter. Therefore, finally, the linear equivalent circuit of the transmitter becomes as shown in FIG. 14, and an equivalent CMOS is obtained using an ideal pulse power supply and resistor. The linear equivalent circuit of the receiver includes on-die termination (ODT) plus a capacitor C equivalent to a parasitic capacitance effect, as shown in FIG. 15. Since the DDR transmits data through multiple equal-length transmission lines in the PCB, adjacent transmission lines cause serious crosstalk. At the same time, if the ports are mismatched, crosstalk also generates multiple reflections on a passive end, which seriously affects the signal integrity. The principle of ODT is to add a terminal resistor to an output end inside a DRAM chip to match the impedance of the output end, thereby eliminating reflection and crosstalk.

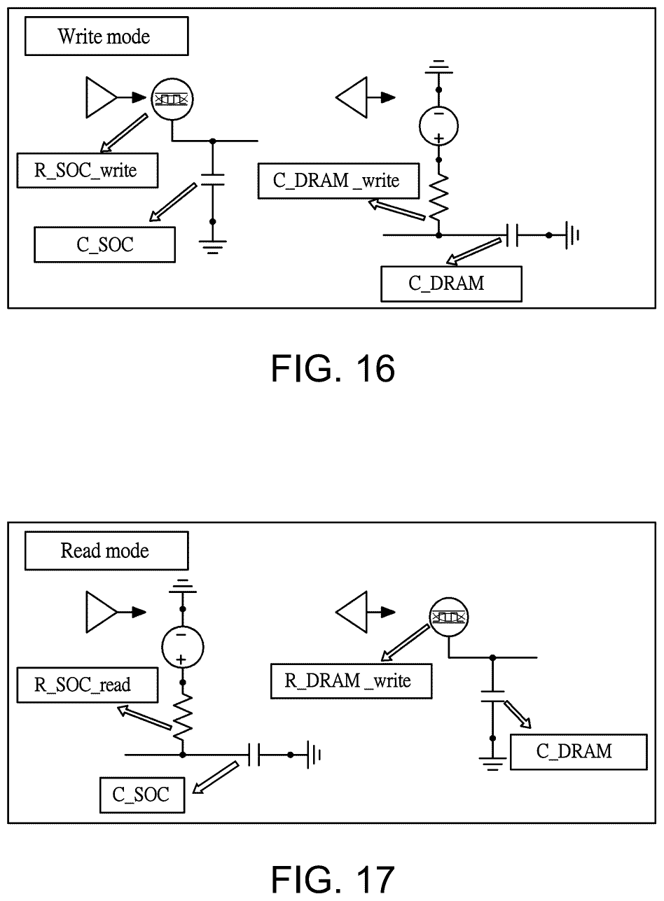

In the “write” mode, the SOC end is in the transmitter mode and the DRAM end is in the receiver mode. As shown in FIG. 16, the linear equivalent circuit at the SOC end is composed of an ideal pulse power supply including an internal resistor and connected in parallel with a capacitor. The linear equivalent circuit at the DRAM end includes ODT and a storage capacitor. In the “read” mode, the SOC end is in the receiver mode and the DRAM end is in the transmitter mode, as shown in FIG. 17.

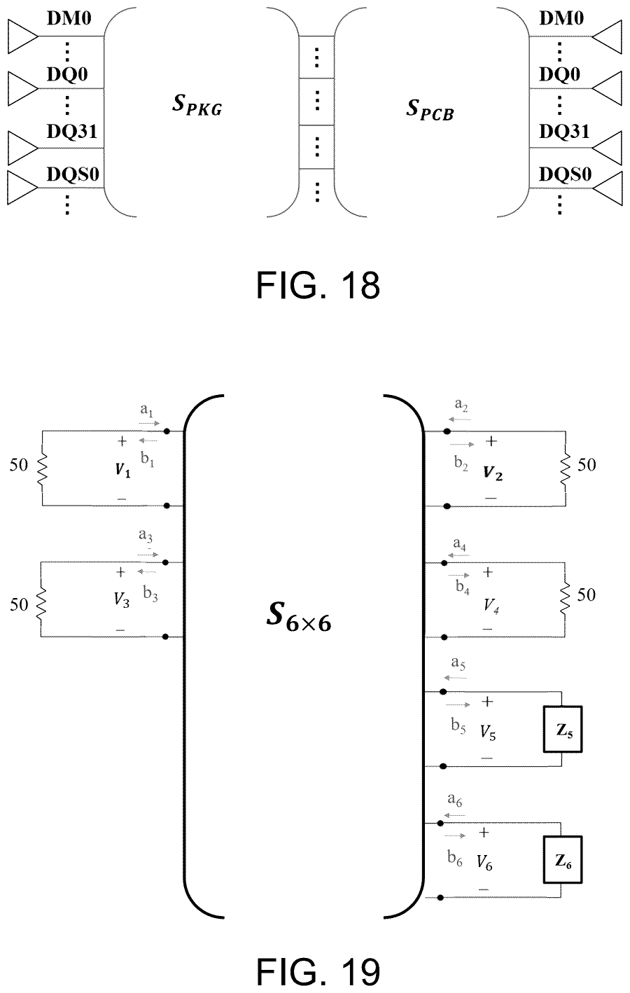

Next, S-parameter preprocessing and peak distortion analysis including a clock signal are explained. First, the S-parameter preprocessing is explained. The circuit of FIG. 18 includes the S-parameters of the PKG and the PCB, but does not include ports of a PWR and a CAP. The embodiment uses the circuit of FIG. 12 for validation. The difference from FIG. 18 lies in the S-parameters of the PCB. The S-parameters of the PCB of FIG. 12 include the ports of the power supply line PWR and the decoupling capacitor CAP. Therefore, the embodiment processes the S-parameters of the PCB to be reduced to the S-parameters that do not include the power supply line PWR and the decoupling capacitor CAP.

Taking FIG. 19 as an example here, ports V₁ and V₂ are of a first signal line, ports V₃ and V₄ are of a second signal line, and ports V₅ and V₆ may respectively represent the ports of the power supply line and the decoupling capacitor. Finally, it is intended to obtain the S-parameters reduced to include only the ports V₁, V₂, V₃, and V₄ and considering the effects of the ports V₅ and V₆. First, an S-parameter matrix S1 may be listed as:

$$( \begin{matrix}{b}_{1} \\ {b}_{2} \\ {b}_{3} \\ {b}_{4} \\ {b}_{5} \\ {b}_{6}\end{matrix} ) = ( \begin{matrix}{S}_{11} & {S}_{12} & {S}_{13} & {S}_{14} & {S}_{15} & {S}_{16} \\ {S}_{21} & {S}_{22} & {S}_{23} & {S}_{24} & {S}_{25} & {S}_{26} \\ {S}_{31} & {S}_{32} & {S}_{33} & {S}_{34} & {S}_{35} & {S}_{36} \\ {S}_{41} & {S}_{42} & {S}_{43} & {S}_{44} & {S}_{45} & {S}_{46} \\ {S}_{51} & {S}_{52} & {S}_{53} & {S}_{54} & {S}_{55} & {S}_{56} \\ {S}_{61} & {S}_{62} & {S}_{63} & {S}_{64} & {S}_{65} & {S}_{66}\end{matrix} ) ( \begin{matrix}{a}_{1} \\ {a}_{2} \\ {a}_{3} \\ {a}_{4} \\ {a}_{5} \\ {a}_{6}\end{matrix} ) \qquad ( 29 )$$

where the 6×6 S-parameter matrix S1 is split into 4 matrices A, B, C, and D, which may be listed as:

$$( \begin{matrix}{S}_{11} & {S}_{12} & {S}_{13} & {S}_{14} & {S}_{15} & {S}_{16} \\ {S}_{21} & {S}_{22} & {S}_{23} & {S}_{24} & {S}_{25} & {S}_{26} \\ {S}_{31} & {S}_{32} & {S}_{33} & {S}_{34} & {S}_{35} & {S}_{36} \\ {S}_{41} & {S}_{42} & {S}_{43} & {S}_{44} & {S}_{45} & {S}_{46} \\ {S}_{51} & {S}_{52} & {S}_{53} & {S}_{54} & {S}_{55} & {S}_{56} \\ {S}_{61} & {S}_{62} & {S}_{63} & {S}_{64} & {S}_{65} & {S}_{66}\end{matrix} ) = ( \begin{matrix}{A}_{4 \times 4} & {B}_{4 \times 2} \\ {C}_{2 \times 4} & {D}_{2 \times 2}\end{matrix} ) \qquad ( 30 )$$

The relationships between a₅ and b₅ and a₆ and b₆ are as follows:

$${a}_{5} = {Γ}_{5} {b}_{5} \\ {Γ}_{5} = \frac{{Z}_{5} - {Z}_{0}}{{Z}_{5} + {Z}_{0}} \\ {a}_{6} = {Γ}_{6} {b}_{6} \\ {Γ}_{6} = \frac{{Z}_{6} - {Z}_{0}}{{Z}_{6} + {Z}_{0}}$$

where Z₅ and Z₆ are load impedances of the ports V₅ and V₆ as shown in FIG. 19, Z₀ is a system impedance of the S-parameters, and Γ₅ and Γ₆ are the reflection coefficients at the receiver end. Then, from (29), (30), and the relationships between a₅ and b₅ and a₆ and b₆, the following may be obtained:

$$( \begin{matrix}{b}_{5} \\ {b}_{6}\end{matrix} ) = ( \begin{matrix}\frac{1}{{Γ}_{5}} & 0 \\ 0 & \frac{1}{{Γ}_{6}}\end{matrix} ) ( \begin{matrix}{a}_{5} \\ {a}_{6}\end{matrix} ) = {C}_{2 \times 4} ( \begin{matrix}{a}_{1} \\ {a}_{2} \\ {a}_{3} \\ {a}_{4}\end{matrix} ) + {D}_{2 \times 2} ( \begin{matrix}{a}_{5} \\ {a}_{6}\end{matrix} )$$

After sorting the above equation, the following may be obtained:

$$( ( \begin{matrix}\frac{1}{{Γ}_{5}} & 0 \\ 0 & \frac{1}{{Γ}_{6}}\end{matrix} ) - {D}_{2 \times 2} ) ( \begin{matrix}{a}_{5} \\ {a}_{6}\end{matrix} ) = {E}_{2 \times 2} ( \begin{matrix}{a}_{5} \\ {a}_{6}\end{matrix} ) = {C}_{2 \times 4} ( \begin{matrix}{a}_{1} \\ {a}_{2} \\ {a}_{3} \\ {a}_{4}\end{matrix} )$$

where a matrix E is:

$${E}_{2 \times 2} = ( \begin{matrix}\frac{1}{{Γ}_{5}} & 0 \\ 0 & \frac{1}{{Γ}_{6}}\end{matrix} ) - {D}_{2 \times 2}$$

Then, the inverse matrix operation is performed on the matrix E to obtain the relationship between a₁ to a₆:

$$( \begin{matrix}{a}_{5} \\ {a}_{6}\end{matrix} ) = {( {E}_{2 \times 2} )}^{- 1} {C}_{2 \times 4} ( \begin{matrix}{a}_{1} \\ {a}_{2} \\ {a}_{3} \\ {a}_{4}\end{matrix} )$$

Then, the above equation is substituted back into (29) and (30) to obtain:

$$( \begin{matrix}{b}_{1} \\ {b}_{2} \\ {b}_{3} \\ {b}_{4}\end{matrix} ) = {A}_{4 \times 4} ( \begin{matrix}{a}_{1} \\ {a}_{2} \\ {a}_{3} \\ {a}_{4}\end{matrix} ) + {B}_{4 \times 2} ( \begin{matrix}{a}_{5} \\ {a}_{6}\end{matrix} ) = ( {A}_{4 \times 4} + {{B}_{4 \times 2} ( {E}_{2 \times 2} )}^{- 1} {C}_{2 \times 4} ) ( \begin{matrix}{a}_{1} \\ {a}_{2} \\ {a}_{3} \\ {a}_{4}\end{matrix} )$$

From the relationships between b₁ to b₄ and a₁ to a₄, an S-parameter matrix S2 may be obtained as:

$$S {2}_{4 \times 4} = {A}_{4 \times 4} + {{B}_{4 \times 2} ( {E}_{2 \times 2} )}^{- 1} {C}_{2 \times 4}$$

where S2 is the S-parameter matrix that includes the effects of the ports V₅ and V₆ and is reduced to include only the ports V₁, V₂, V₃, and V₄. The derivation manner of the embodiment may be extended to multiple signal lines and multiple power supply line ports or decoupling capacitor ports, and is not limited to the case of two signal lines. Therefore, the issue that the S-parameters of the PCB have several more power supply line ports and decoupling capacitor ports in FIG. 12 may be solved.

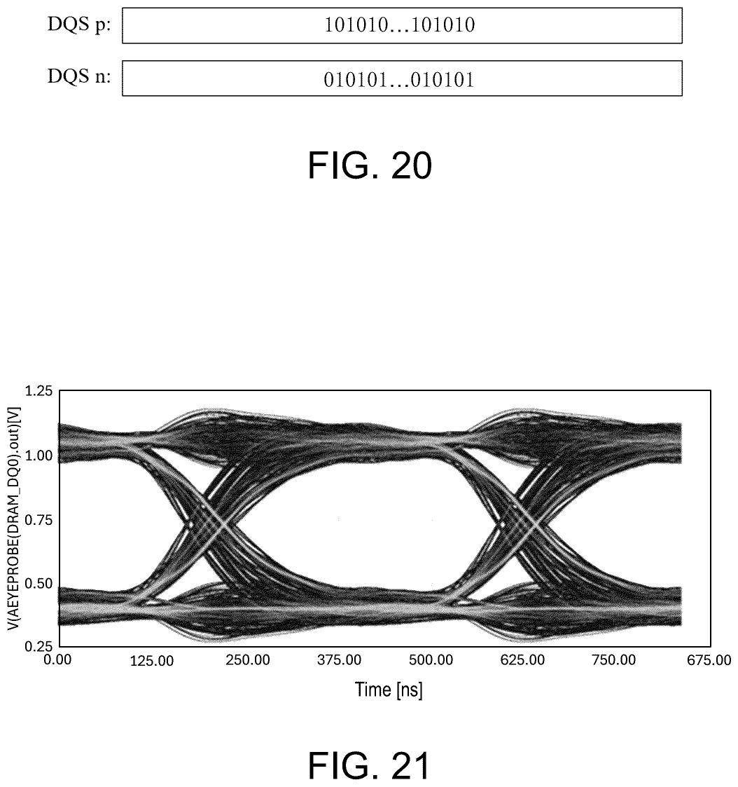

Next, the peak distortion analysis including the clock signal is explained. The DQS of FIG. 12 is a differential signal line for indicating timing, so the input sequence is as shown in FIG. 20. Since the DQS is a pair of differential signal lines, sequences of positive and negative ends are inverted. In Equation (15), the worst eye height may be obtained by the cursor of the main signal line deducted by the absolute values of all ISI. However, since signals of the DQS are fixed at ‘1010 . . . ’ and ‘0101 . . . ’, if the original Equation (15) is used, the actual eye height is underestimated, so a correction is made here for the peak distortion analysis including the clock signal.

Therefore, for Equation (15), considering the sum of crosstalk of the DQS and crosstalk caused by remaining coupled lines, (31) may be listed:

$$Worst eye height = {Main}_{0} - {\sum }_{k = - L \& k \neq 0}^{N} \vert {Main}_{k} \vert - {\sum }_{j} {\sum }_{l = - P}^{M - 1} \vert {Xtk}_{l}^{j} \vert + {Xtk}_{DQS} \qquad ( 31 )$$

where Xtk_{DQS} represents the sum of crosstalk of the DQS, N represents the number of postcursors considered on the main signal line, L represents the number of precursors considered on the main signal line, M represents the number of Xtk cursors considered on the coupled line, P represents the number of Xtk precursors considered on the coupled line, and j represents different coupled lines.

Xtk_{DQS} is to respectively calculate under which sequences do a worst case 1 and a worst case 0 of DQS p and n have poor ISI sums, as shown in Table 1 below.

TABLE 1

| | Worstcase 1/Worstcase 0 | |
|---|---|---|
| DQS p | 1 0 1 0 . . . | 0 1 0 1 . . . |
| DQS n | 0 1 0 1 . . . | 1 0 1 0 . . . |

In addition, for Equations (1) and (2), considering the sum of crosstalk of the DQS and crosstalk caused by the remaining coupled lines, Equations (1) and (2) may be corrected as:

$$Worst\_ 0 = \sum \vert {ISI}^{+} \vert + \sum \vert {ISI}_{XT}^{+} \vert + \vert {ISI}_{DQS}^{+} \vert \qquad ( 32 )$$

$$Worst\_ 1 = cursor - \sum \vert {ISI}^{-} \vert - \sum \vert {ISI}_{XT}^{-} \vert - \vert {ISI}_{DQS}^{-} \vert \qquad ( 33 )$$

where ISI_{DQS}⁻ is to calculate under which sequence does the worst case 1 of DQS p and n have a smaller ISI sum; and ISI_{DQS}+ is to calculate under which sequence does the worst case 0 of DQS p and n have a greater ISI sum.

FIG. 21 is a worst-case sequence eye diagram obtained using an eye-diagram index analytic method according to an embodiment of the disclosure. In the embodiment, the eye-diagram index such as the eye height, the eye width, etc. may be quickly obtained (such as requiring only 0.8 seconds) using the eye-diagram index analytic method, which can greatly save calculation and simulation time, and compared with the eye diagram obtained using in/out-of-phase PRBS and independent PRBS, the eye-diagram index analytic method is fast and has small error.

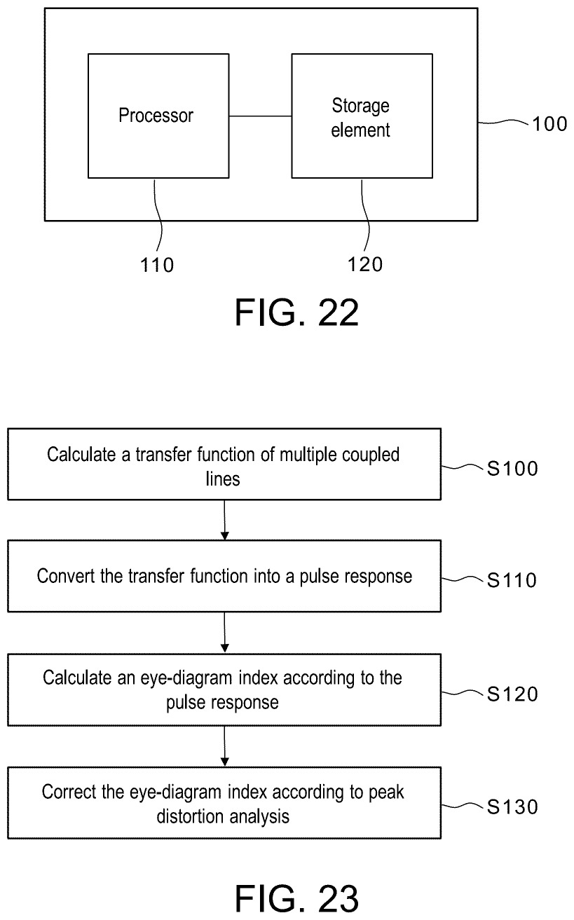

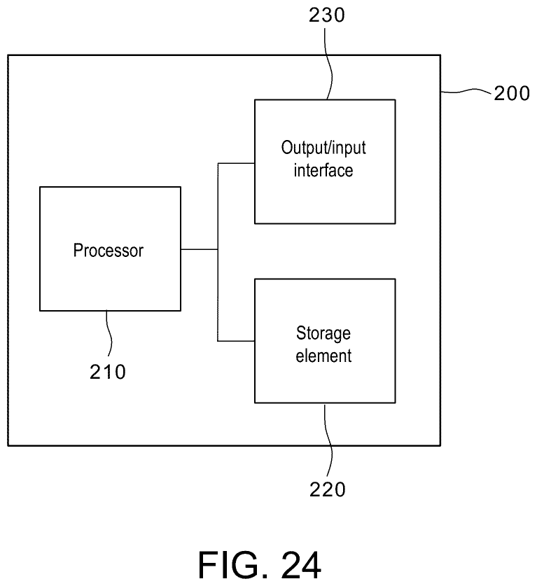

FIG. 22 is a block schematic diagram of an electronic apparatus according to an embodiment of the disclosure. FIG. 23 is a flowchart of steps of an eye-diagram index analytic method according to an embodiment of the disclosure. Please refer to FIG. 22 and FIG. 23. An electronic apparatus 100 includes a processor 110 and a storage element 120. In an embodiment, the electronic apparatus 100 is, for example, a computer, and the storage element 120 is, for example, a computer readable recording medium, including a computer program, enabling the computer to execute the eye-diagram index analytic method of FIG. 23 after executing the computer program. The eye-diagram index analytic method of the embodiment is suitable for analyzing various electronic circuit architectures with multiple transmission lines to find the worst-case sequence patterns in a short time to calculate the eye-diagram index.

Specifically, in Step S100, the processor 110 calculates the transfer function of the transmission line architecture with multiple coupled lines as shown in FIG. 10, such as Equation (27), and the transfer function includes the transfer function of the insertion loss response and the far-end crosstalk response. For example, k=m is the transfer function of the insertion loss response of the k^{th} signal line, and k≠m represents the transfer function of far-end crosstalk caused by the m^{th} signal line to the k^{th} signal line. In addition, the transfer function includes the S-parameter matrix, which is used to describe the frequency domain characteristics of the electronic element between the transmission lines.

For example, the eye-diagram index analytic method of the embodiment may be used to analyze a DDR 4 memory circuit, wherein the DDR 4 memory circuit has a transmission line architecture with multiple coupled lines. The S-parameter matrix may be used to describe the frequency domain characteristics of the electronic element in the DDR 4.

In Step S110, the processor 110 substitutes Equation (27) back into (10) and (11) to convert the transfer function into the pulse response, such as Equation (5). The pulse response includes the pulse response of the insertion loss response and the far-end crosstalk response.

In Step S120, the processor 110 calculates the eye-diagram index according to the pulse response, such as Equations (15) to (18). The eye-diagram index includes the worst eye height of Equation (15), the worst eye width of Equation (16), and the worst center eye height of Equation (18).

In Step S130, the processor 110 corrects the eye-diagram index according to the peak distortion analysis, such as Equation (31). The peak distortion analysis includes the peak distortion analysis of the clock signal. In other words, for Equation (15), the processor 110 may further consider the sum of crosstalk of the DQS and crosstalk caused by the remaining coupled lines, and Equation (15) is corrected into Equation (31).

In an embodiment, for Equations (1) and (2), the processor 110 may also consider the sum of crosstalk of the DQS and crosstalk caused by the remaining coupled lines, and Equations (1) and (2) are corrected into Equations (32) and (33).

In an embodiment, the processor 110 is, for example, a center processing unit (CPU), other programmable general-purpose or specific-purpose micro control units (MCU), microprocessors, digital signal processors (DSP), programmable controllers, application specific integrated circuits (ASIC), graphics processing units (GPU), image signal processors (ISP), image processing units (IPU), arithmetic logic units (ALU), complex programmable logic devices (CPLD), field programmable gate arrays (FPGA), other similar elements, or a combination of the above elements.

In an embodiment, the storage element 120 is used to store various software, data, and various program codes required when the electronic apparatus 100 is running. The storage medium 120 is, for example, any type of fixed or removable random access memory (RAM), read-only memory (ROM), flash memory, hard disk drive (HDD), solid state drive (SSD), similar elements, or a combination of the above elements and is used to store multiple modules or various applications that may be executed by the processor 110. In an embodiment, the storage element 120 may further include a database.

In addition, sufficient teachings, suggestions, and implementation explanations for the eye-diagram index analytic method of the embodiment may be obtained from the description of the embodiments of FIG. 1 to FIG. 21, so there will not be reiteration.

FIG. 24 is a block schematic diagram of an electronic apparatus according to another embodiment of the disclosure. Please refer to FIG. 23 and FIG. 24. An electronic apparatus 200 of the embodiment includes a processor 210, a storage element 220, and an output/input interface 230. The output/input interface 230 is used to receive circuit parameters and output the eye diagram calculated using the eye-diagram index analytic method of FIG. 23.

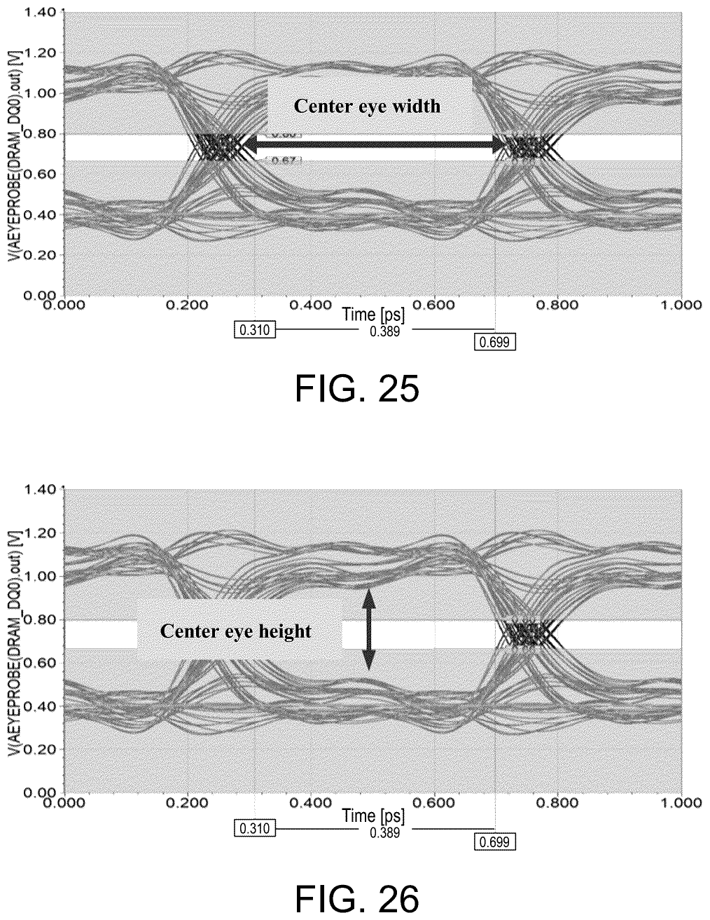

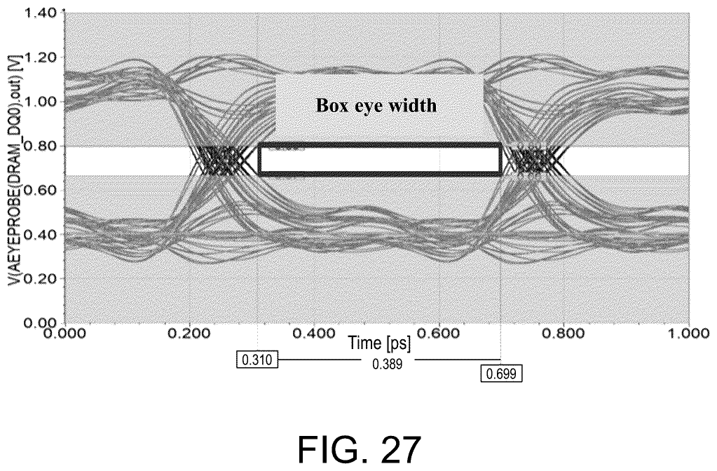

Specifically, the circuit to be calculated by the computer program of the embodiment is, for example, the DDR4 circuit of FIG. 12, which includes the S-parameters of the package (PKG) and the printed circuit board (PCB), the linear equivalent circuit at the SOC end, and the linear equivalent circuit at the DRAM end, and the equivalent circuits at two ends are respectively as shown in FIG. 16 and FIG. 17 according to the different read and write modes. The computer program of the embodiment may calculate the eye-diagram index of DQ0˜31 and DM0˜3 under the circuit, including the worst eye width as shown in FIG. 25, the worst center eye height as shown in FIG. 26, and the box eye width as shown in FIG. 27. The output/input interface 230 is, for example, a display apparatus and may be used to display the eye-diagram index.

The user may input the S-parameters and the value of each element in the linear equivalent circuit and each parameter of the voltage source as shown in FIG. 16 and FIG. 17, as shown in Table 2 below:

TABLE 2

| Item | Description |
|---|---|
| Project name | Project name |
| PKG Sparameter | S-parameters of package |
| PCB Sparameter | S-parameters of printed circuit board |
| R_SOC_write | ‘Write’ mode, resistor at SOC end, unit is ohm |
| R_SOC_read | ‘Read’ mode, resistor at SOC end, unit is ohm |
| C_SOC | Capacitor at SOC end, unit is pF |
| R_DRAM_write | ‘Write’ mode, resistor at DRAM end, unit is ohm |
| R_DRAM_read | ‘Read’ mode, resistor at DRAM end, unit is ohm |
| C_DRAM | Capacitor at DRAM end, unit is pF |
| C_CAP | Capacitor at CAP end, unit is nF |
| | (no input is required if PCB does not have CAP end) |
| Source Voltage | Magnitude of voltage source, unit is V |
| Bit rate | Transmission rate, unit is Gbps |
| Rising Time | Rising time, unit may be UI or ps |
| Box Eyeheight | To calculate box eye width, different box eye |
| | heights may be set according to different |
| | specifications, unit is V |

The output/input interface 230 is, for example, a display apparatus and may be used to display a program window, so that a user may input each parameter through a keyboard, a mouse, touch, etc.

Therefore, the embodiment writes a program based on the eye-diagram index analytic method and establishes a graphical user interface (GUI). Therefore, the user may calculate the eye-diagram index in a simple and intuitive operating environment, and the result is not only directly displayed in the interface, but also stored in a file to provide the user with further analysis.

In addition, sufficient teachings, suggestions, and implementation explanations for the eye-diagram index analytic method of the embodiment may be obtained from the description of the embodiments of FIG. 1 to FIG. 23, so there will not be reiteration.

An application scenario of the eye-diagram index analytic method according to the embodiment of the disclosure is described below. The eye-diagram index analytic method according to the embodiment of the disclosure may be used to validate whether the package carrying the chip and the transmission signal quality of the printed circuit board meet the requirements after the chip circuit design. There are several reasons that affect the package and the transmission signal quality of the printed circuit board, loss, reflection, crosstalk, and equivalent load at the circuit end.

The general method to validate signal quality is to simulate with a circuit simulation software through connecting a chip circuit model, a PKG model, and a PCB model in series. However, such a simulation validation method requires more time if multiple signal lines are to be validated. Therefore, the eye-diagram index analytic method of the embodiment of the disclosure may be used to first screen out signal lines that may have poor transmission signal quality, then check the package and the layout design of the printed circuit board, and make modification.

In an embodiment, the eye-diagram index analytic method may be integrated into an electronic design automation (EDA) tool, and the EDA tool may even be provided as a reference for modification. In an embodiment, input data required by the eye-diagram index analytic method includes a package channel model carrying the chip, a printed circuit board channel model connected to the chip package, and input parameters. The input parameters vary according to a circuit under test and functions. Taking the test of DDR transmission quality as an example, the parameters that need to be input include voltage source, transmission rate, write mode, read mode, circuit equivalent resistance load, circuit equivalent capacitance load, and eye height voltage.

In summary, in the embodiment of the disclosure, the eye-diagram index analytic method of multiple coupled transmission lines is provided. First, the transfer function under mismatched boundaries is derived, the pulse response may be then obtained using inverse Fourier transform, and each index of the eye diagram may be obtained based on the peak distortion analysis, which can greatly improve the design and optimization efficiency. The eye-diagram index analytic method of the embodiment of the disclosure can more effectively and accurately determine the signal integrity of different signal lines than other methods.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. An eye-diagram index analytic method, comprising:
calculating a transfer function of a plurality of coupled lines;
converting the transfer function into a pulse response;
calculating an eye-diagram index according to the pulse response; and
correcting the eye diagram index according to peak distortion analysis.

2. The eye-diagram index analytic method according to claim 1, wherein the transfer function comprises an S-parameter matrix, and the S-parameter matrix is used to describe a frequency domain characteristic of an electronic element between transmission lines.

3. The eye-diagram index analytic method according to claim 2, wherein the electronic element is an electronic element in a double data rate memory circuit.

4. The eye-diagram index analytic method according to claim 1, wherein the transfer function comprises a transfer function of an insertion loss response and a far-end crosstalk response.

5. The eye-diagram index analytic method according to claim 1, wherein the pulse response comprises a pulse response of the insertion loss response and the far-end crosstalk response.

6. The eye-diagram index analytic method according to claim 1, wherein the eye-diagram index comprises at least one of a worst eye height, a worst eye width, a worst center eye height, and a box eye width.

7. The eye-diagram index analytic method according to claim 1, wherein the peak distortion analysis comprises peak distortion analysis of a clock signal.

8. A computer readable recording medium, comprising a computer program, enabling a computer to execute the eye-diagram index analytic method according to claim 1 after executing the computer program.

9. An electronic apparatus, comprising a processor and a storage element, the storage element storing a computer program, enabling the processor to execute the eye-diagram index analytic method according to claim 1 after executing the computer program.

10. The electronic apparatus according to claim 9, further comprising an output/input interface for receiving a circuit parameter and outputting an eye diagram calculated using the eye-diagram index analytic method.
